(19) United States
(12) Patent Application Publication
(10) Pub. No.: US 2024/0145243 A1
(43) Pub. Date: May 2, 2024

(54) LASER ANNEALING METHOD AND METHOD OF MANUFACTURING DISPLAY DEVICE USING THE SAME

(71) Applicant: SAMSUNG DISPLAY CO., LTD., Yongin-si (KR)

(72) Inventors: CHEOLHO PARK, Yongin-si (KR); JEKIL RYU, Yongin-si (KR); JEONGHUN WOO, Yongin-si (KR); DOO-WON LEE, Yongin-si (KR); HAESOOK LEE, Yongin-si (KR); JIN HONG JEUN, Yongin-si (KR)

(21) Appl. No.: 18/235,797

(22) Filed: Aug. 18, 2023

(30) Foreign Application Priority Data
Nov. 2, 2022 (KR) 10-2022-0144422

(51) Int. Cl. H01L 21/02

(52) U.S. Cl. CPC H01L 21/02686; H01L 21/02691; H10K 59/1201

(57) ABSTRACT

A laser annealing method includes selecting a reference intensity from a plurality of intensities of a plurality of peaks; where the reference intensity is used to determine a pulse shape of laser irradiation during laser annealing, setting the pulse shape by setting an intensity ratio of a first peak having a smallest peak occurrence time among the plurality of peaks to less than about 100 percent relative to the reference intensity, and irradiating a laser beam having the pulse shape to a stage.

This application claims priority to Korean Patent Application No. 10-2022-0144422 filed on Nov. 2, 2022, and all the benefits accruing therefrom under 35 U.S.C. § 119, the content of which in its entirety is herein incorporated by reference.

### BACKGROUND

### 1. Field

The present disclosure relates to a laser annealing method and a method of manufacturing a display device using the same. More particularly, the present disclosure relates to a laser annealing method using a solid laser medium and a method of manufacturing a display device using the same.

### 2. Description of the Related Art

In a manufacturing process of a display device, a dehydrogenation process and an annealing process may be performed. The display device may include an insulating layer and an active layer sequentially stacked on a substrate. The active layer may include amorphous silicon. The amorphous silicon may be crystallized through the annealing process.

A dehydrogenation process may be performed before an annealing process to reduce the hydrogen content of the active layer. An insulating layer may be a high hydrogen thin film (i.e., the insulating layer may have a greater hydrogen content than other layers included in the display device). The hydrogen included in the insulating layer may not escape to outside during the dehydrogenation process. The hydrogen that has not escaped to the outside may diffuse to the active layer. Accordingly, defects such as film bursting may occur on a surface of the active layer.

### SUMMARY

The present disclosure may provide a laser annealing method with an improved process margin.

The present disclosure may provide a method of manufacturing the display device using the laser annealing method.

In an embodiment, a laser annealing method includes selecting a reference intensity from a plurality of intensities of a plurality of peaks; where the reference intensity is used to determine a pulse shape of laser irradiation during laser annealing; setting the pulse shape by setting an intensity ratio of a first peak having a smallest peak occurrence time among the plurality of peaks to less than about 100 percent relative to the reference intensity; and irradiating a laser beam having the pulse shape to a stage.

In an embodiment, the pulse shape may further include a second peak, a third peak, a fourth peak, and a fifth peak. Each of the second peak, the third peak, the fourth peak, and the fifth peak may occur sequentially after occurrence of the first peak. The intensity ratio of each of the first peak, the second peak, the fourth peak, and the fifth peak may be set using a height value of the third peak as the reference intensity.

In an embodiment, the intensity ratio of the first peak relative to the third peak is about 60 percent to about 70 percent.

In an embodiment, the intensity ratio of the fifth peak relative to the third peak is about 50 percent to about 65 percent.

In an embodiment, pulse duration between the first peak and the third peak is about 43 nanoseconds to about 51 nanoseconds.

In an embodiment, the intensity ratio of the first peak relative to the third peak is about 24 percent to about 32 percent.

In an embodiment, the intensity ratio of the fifth peak relative to the third peak is about 54 percent or more to about 62 percent.

In an embodiment, the pulse duration between the first peak and the third peak is about 62 nanoseconds to about 74 nanoseconds. The pulse duration between the first peak and the fifth peak is about 104 nanoseconds to about 116 nanoseconds.

In an embodiment, the pulse shape may further include a second peak, a third peak, a fourth peak, a fifth peak, a sixth peak, and a seventh peak. Each of the second peak, the third peak, the fourth peak, and the fifth peak, a sixth peak, and the seventh peak may occur sequentially after occurrence of the first peak. The intensity ratio of each of the first peak, the second peak, the third peak, the fourth peak, the sixth peak, and the seventh peak maybe set using a height value of the fifth peak as the reference intensity.

In an embodiment, the intensity ratio of the first peak relative to the fifth peak is about 18 percent to about 26 percent.

In an embodiment, the intensity ratio of the third peak relative to the fifth peak is about 30 percent to about 40 percent. The intensity ratio of the seventh peak relative to the fifth peak is about 60 percent to about 75 percent.

In an embodiment, pulse duration between the first peak and the third peak is about 38 nanoseconds to about 46 nanoseconds. The pulse duration between the first peak and the fifth peak is about 83 nanoseconds to about 91 nanoseconds. The pulse duration between the first peak and the seventh peak is about 129 nanoseconds to about 137 nanoseconds.

In an embodiment, the intensity ratio of the third peak relative to the fifth peak is about 31 percent to about 39 percent. The intensity ratio of the seventh peak relative to the fifth peak is about 61 percent to about 70 percent.

In an embodiment, the pulse duration between the first peak and the third peak is about 52 nanoseconds to about 64 nanoseconds. The pulse duration between the first peak and the fifth peak is about 98 nanoseconds to about 110 nanoseconds. The pulse duration between the first peak and the seventh peak is about 133 nanoseconds to about 143 nanoseconds.

In an embodiment, the irradiating of the laser beam to the stage may include setting the laser beam having a first energy density, first scanning the stage using the laser beam irradiating in a shape of a line beam extending in a first direction, irradiating in a shape of a line beam along a second direction perpendicular to the first direction, setting the laser beam having a second energy density larger than the first energy density, and second scanning the stage using the laser beam having the second energy density, along an opposite direction to the second direction.

The method of manufacturing a display device includes forming a preliminary active layer including amorphous silicon on a substrate, setting a reference intensity for determining a pulse shape which includes a plurality of peaks, setting the pulse shape having an intensity ratio of a first peak having a smallest peak occurrence time among the plurality of peaks less than about 100 percent relative to the reference intensity, and annealing the preliminary active layer by irradiating a laser beam having the pulse shape.

In an embodiment, the pulse shape may further include a second peak, a third peak, a fourth peak, and a fifth peak. Each of the second peak, the third peak, the fourth peak, and the fifth peak may occur sequentially after occurrence of the first peak. The intensity ratio of each of the first peak, the second peak, the fourth peak, and the fifth peak maybe set using a height value of the third peak as the reference intensity. The intensity ratio of the first peak relative to the third peak is about 60 percent to about 70 percent. The intensity ratio of the fifth peak relative to the third peak is about 50 percent to about 65 percent. Pulse duration between the first peak and the third peak is about 43 nanoseconds to about 51 nanoseconds.

In an embodiment, the pulse shape may further include a second peak, a third peak, a fourth peak, and a fifth peak. Each of the second peak, the third peak, the fourth peak, and the fifth peak may occur sequentially after occurrence of the first peak. The intensity ratio of each of the first peak, the second peak, the fourth peak, and the fifth peak is set using a height value of the third peak as the reference intensity. The intensity ratio of the first peak relative to the third peak is about 24 percent to about 32 percent. The intensity ratio of the fifth peak relative to the third peak is about 54 percent to about 62 percent. Pulse duration between the first peak and the third peak is about 62 nanoseconds to about 74 nanoseconds. The pulse duration between the first peak and the fifth peak is about 104 nanoseconds to about 116 nanoseconds.

In an embodiment, the pulse shape may include the first peak, a second peak, a third peak, a fourth peak, a fifth peak, a sixth peak, and a seventh peak. Each of the second peak, the third peak, the fourth peak, and the fifth peak, a sixth peak, and the seventh peak may occur sequentially after occurrence of the first peak. The intensity ratio of each of the first peak, the second peak, the fourth peak, and the fifth peak is set using a height value of the fifth peak as the reference intensity. The intensity ratio of the first peak relative to the fifth peak is about 18 percent to about 26 percent. The intensity ratio of the third peak relative to the fifth peak is about 30 percent to about 40 percent. The intensity ratio of the seventh peak relative to the fifth peak is about 60 percent to about 75 percent. Pulse duration between the first peak and the third peak is about 38 nanoseconds to about 46 nanoseconds. The pulse duration between the first peak and the fifth peak is about 83 nanoseconds to about 91 nanoseconds. The pulse duration between the first peak and the seventh peak is about 129 nanoseconds to about 137 nanoseconds.

In an embodiment, the pulse shape may include the first peak, a second peak, a third peak, a fourth peak, a fifth peak, a sixth peak, and a seventh peak. Each of the second peak, the third peak, the fourth peak, and the fifth peak, a sixth peak, and the seventh peak may occur sequentially after occurrence of the first peak. The intensity ratio of each of the first peak, the second peak, the fourth peak, and the fifth peak is set using a height value of the fifth peak as the reference intensity. The intensity ratio of the first peak relative to the fifth peak is about 18 percent to about 26 percent. The intensity ratio of the third peak relative to the fifth peak is about 31 percent to about 39 percent. The intensity ratio of the seventh peak relative to the fifth peak is about 61 percent to about 70 percent. Pulse duration between the first peak and the third peak is about 52 nanoseconds to about 64 nanoseconds. The pulse duration between the first peak and the fifth peak is about 98 nanoseconds to about 110 nanoseconds. The pulse duration between the first peak and the seventh peak is about 133 nanoseconds to about 143 nanoseconds.

The laser annealing method and the method of manufacturing the display device using the laser annealing method according to the embodiments of the present disclosure may be set by the reference intensity for determining the pulse shape including the plurality of peaks. The pulse shape may be obtained by setting the intensity ratio of the first peak having smallest peak occurrence time among the plurality of peaks less than about 100 percent relative to the reference intensity. The laser beam having the pulse shape may be irradiated to the stage. Gradual dehydrogenation may be induced by irradiating the laser beam having the pulse shape in which the intensity ratio of the first peak relative to the reference intensity is less than about 100 percent on the stage. Accordingly, the occurrence of the defects such as film bursting may be prevented, and annealing uniformity may be improved.

### BRIEF DESCRIPTION OF THE DRAWINGS

Illustrative, non-limiting embodiments will be more clearly understood from the following detailed description in conjunction with the accompanying drawings.

FIG. 1 is a block diagram illustrating a laser annealing apparatus according to an embodiment of the present disclosure.

FIGS. 2 and 3 are graphs illustrating pulse shapes set by the laser annealing apparatus of FIG. 1.

FIG. 4 is a perspective view illustrating the laser annealing method according to an embodiment of the present disclosure.

FIGS. 5, 6, 7, 8, 9, 10, and 11 are cross-sectional views illustrating a method of manufacturing a display device according to another embodiment of the present disclosure using the laser annealing method according to an embodiment of the present disclosure.

FIGS. 12 and 13 are graphs illustrating other pulse shapes set by the laser annealing apparatus of FIG. 1.

### DETAILED DESCRIPTION

Hereinafter, embodiments of the present disclosure will be described in more detail with reference to the accompanying drawings. The same or similar reference numerals are used for the same components in the drawings, and redundant descriptions of the same components will be omitted.

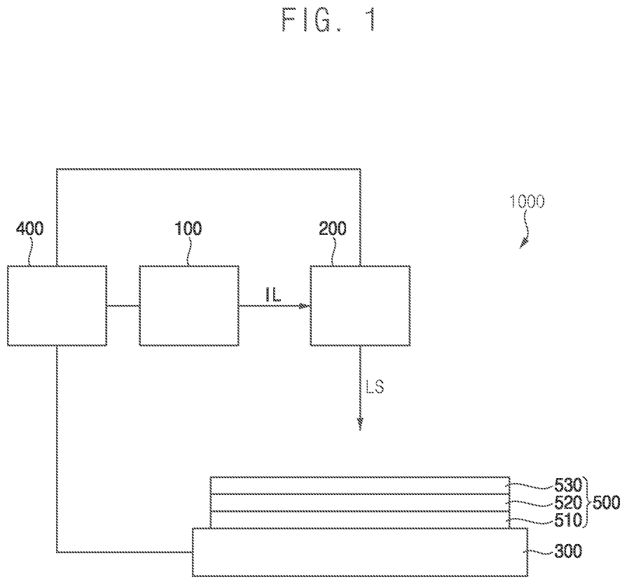

FIG. 1 is a block diagram illustrating a laser annealing apparatus according to an embodiment of the present disclosure.

Referring to FIG. 1, the laser annealing apparatus 1000 according to an embodiment of the present disclosure may include a laser generator 100, an optical system 200, a stage 300, and a controller 400. Here, the laser annealing apparatus 1000 may be an apparatus capable of performing a laser annealing process.

The laser generator 100 may generate an input light IL. For example, the input light IL may be a solid laser. The laser generator 100 may be plural (i.e., it can generate a plurality of lasers simultaneously).

The optical system 200 may convert the input light IL of the laser generator 100 into a laser beam LS into at least one output light beam. For example, the laser beam LS may be converted into a line beam to scan an object 500 disposed on the stage 300.

The optical system 200 may be disposed in an optical path of the laser beam LS. The laser annealing apparatus 1000 may further include a plurality of optical systems capable of performing functions independently of the optical system 200. For example, the plurality of optical systems may include a beam splitter capable of splitting the beam, a mirror capable of changing a beam path (i.e., the optical path), a galvanometer scanner, or the like.

The stage 300 may provide a flat surface on which the object 500 may be seated. The laser annealing apparatus 1000 may further include a driving part capable of moving the stage 300. The driving part may be disposed under or one side of the stage 300. Accordingly, the stage 300 may move at a constant speed in one direction.

The controller 400 may control an operation of each of the laser generator 100, the optical system 200, and the stage 300.

The controller 400 may control a frequency, a pulse width, pulse duration, and the like, of the laser generator 100. The controller 400 may control a beam profile, an angle, and the like (of the beam) passing through the optical system 200. The controller 400 may control a movement speed, a movement direction, and the like, of the stage 300. However, the present disclosure may not be limited thereto. The controller 400 may control various operations of each of the laser generator 100, the optical system 200, and the stage 300.

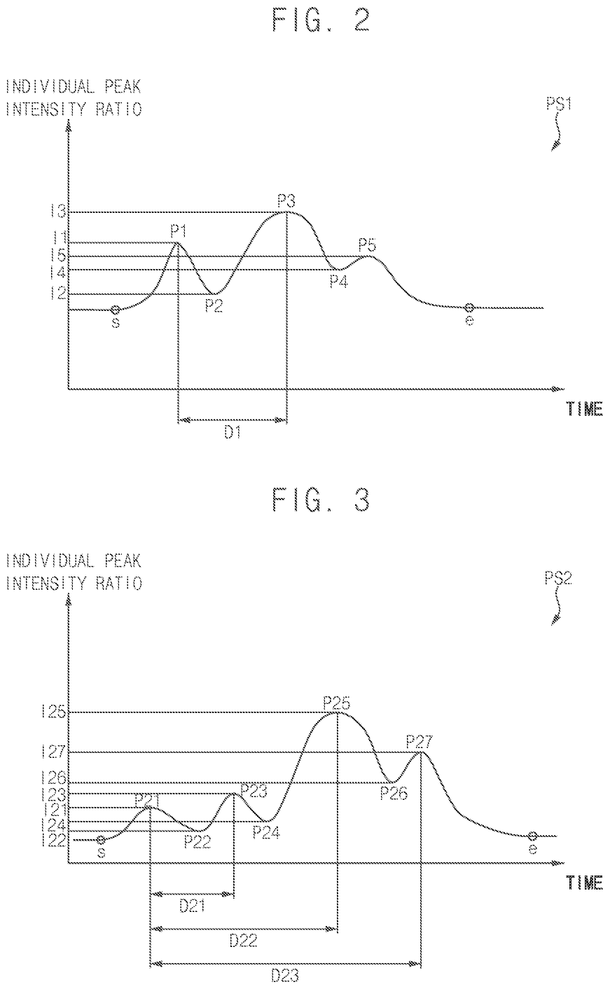

The controller 400 may set a pulse shape of the input light IL. One laser generator 100 may emit the input light IL having a pulse shape including a Gaussian peak. The laser annealing apparatus 1000 may include a plurality of the laser generators 100 to prevent the occurrence of the defects by inducing gradual dehydrogenation. A plurality of the input light IL emitted from the plurality of the laser generators 100 may generate various pulse shapes by applying a time delay called a sync offset. A detailed description of the pulse shape will be described later with reference to FIGS. 2, 3, 12, and 13.

The object 500 may include a substrate 510, an insulating layer 520, and a preliminary active layer 530.

The substrate 510 may include a flexible material or a rigid material. For example, the flexible material may include a polymer such as polyimide (PI), a polyolefin, a polyaramid, a polyimide amide, a polyester, a polycarbonate, a polyarylene ether, and the like, or a combination thereof. In addition, the rigid material may include a glass, and the like.

The insulating layer 520 may be disposed on the substrate 510. For example, the insulating layer 520 may include silicon oxide (SiO), silicon nitride (SiN), silicon oxynitride (SiON), silicon oxycarbide (SiOC), silicon carbonitride (SiCN), aluminum oxide (AlO), aluminum nitride (AlN), tantalum oxide (TaO), hafnium oxide (HfO), zirconium oxide (ZrO), titanium oxide (TiO), and the like, or a combination thereof. These may be used alone or in combination with each other.

The preliminary active layer 530 may be disposed on the insulating layer 520. For example, the preliminary active layer 530 may include amorphous silicon (a-Si). The laser beam LS generated from the laser generator 100 may be directed to irradiate the object 500 seated on the stage 300. During the irradiation, the stage 300 may move at the constant speed in the one direction. Alternatively, the stage 300 may be fixed, and the laser beam LS may be moved and directed to irradiate the stage 300.

The laser beam LS may perform a dehydrogenation process or an annealing process according to a set energy density value.

In addition, the laser annealing apparatus 1000 may further include a sensor. For example, the sensor may be a photodiode. The sensor may be disposed in the optical path. The pulse shape may be checked by using the sensor.

FIGS. 2 and 3 are graphs illustrating pulse shapes set by the laser annealing apparatus of FIG. 1.

Referring to FIGS. 1, 2, and 3, the controller 400 included in the laser annealing apparatus 1000 may set the pulse shape PS1 or PS2. The pulse shape PS1 or PS2 may be set such that an individual peak intensity ratio (hereinafter, referred an intensity ratio) I1 or I21 of the first peak P1 or P21 is less than about 100 percent (%) relative to a reference intensity. The laser annealing apparatus 1000 may perform the dehydrogenation process first, and then the annealing process, to prevent the occurrence of defects such as film bursting.

As shown in FIG. 2, a first pulse shape PS1 may include a plurality of peaks. In an embodiment, the first pulse shape PS1 may include a first peak P1, a second peak P2, a third peak P3, a fourth peak P4, and a fifth peak P5. The first peak P1 may have a smallest peak occurrence time among the plurality of peaks. The second peak P2, the third peak P3, the fourth peak P4, and the fifth peak P5 may sequentially occur after the first peak P1 occurs. In other words, the second peak P2 may occur later than the first peak P1, the third peak P3 may occur later than the second peak P2, the fourth peak P4 may occur later than the third peak P3, and the fifth peak P5 may occur later than the fourth peak P4.

An individual intensity ratio of each of the plurality of peaks may be calculated by dividing the individual intensity of each of the plurality of peaks by the reference intensity. The reference intensity is typically the highest peak intensity of the plurality of peaks. The individual intensity ratio is obtained by dividing the individual intensity of each peak by the highest peak intensity of the plurality of peaks. The reference intensity may be a value for determining the first pulse shape PS1 including the plurality of peaks.

In an embodiment, the first pulse shape PS1 may be set so that the intensity ratio I1 of the first peak P1 is less than about 100% relative to the reference intensity. The reference intensity may be equal to a height value of the third peak P3. In other words, a value obtained by dividing an intensity of the first peak P1 by an intensity of the third peak P3 may be less than about 100%.

An intensity ratio I1 of the first peak P1, an intensity ratio I2 of the second peak P2, an intensity ratio I4 of the fourth peak P4, and an intensity ratio I5 of the fifth peak P5 may each be set using the height value of the third peak P3 as the reference intensity. Accordingly, the intensity ratio I3 of the third peak P3 maybe 100% as a maximum value. The individual intensity ratio of each of the plurality of peaks relative to the third peak P3 may be as follows. In an embodiment, the intensity ratio I1 of the first peak P1 may be about 60% to about 70%, the intensity ratio I2 of the second peak P2 may be about 10% to about 20%, the intensity ratio I4 of the fourth peak P4 may be about 35% to about 45%, and the intensity ratio I5 of the fifth peak P5 may be about 50% to about 65%. Among each of the intensity ratio of the peaks, in the dehydrogenation process and the annealing process, the intensity ratio I1 of the first peak P1 and the intensity ratio I5 of the fifth peak P5 relative to the third peak P3 may be important.

Processing with the laser beam LS using a height value of the first peak P1 as the reference intensity results in the formation of defects due to heat accumulation in the object 500. For example, when the object 500 is destroyed and analyzed after the processing, yellowing is found at a rim part (of the object 500) and other defects such as the film bursting may occur.

However, when processing using the laser beam LS is conducted with the height value of the third peak P3 being used as the reference intensity (instead of the first peak P1), the occurrence of the defects may be minimized or even prevented.

When the intensity ratio I1 of the first peak P1 relative to the third peak P3 is less than about 60%, the intensity ratio I1 of the first peak P1 relative to the third peak P3 may be insufficient to induce the dehydrogenation from a thin film (e.g., the insulating layer 520 and the preliminary active layer 530 of FIG. 1). Accordingly, since the hydrogen content of the thin film is not sufficiently lowered, the defects such as the film bursting may occur.

When the intensity ratio I1 of the first peak P1 relative to the third peak P3 exceeds about 70%, the annealing of the preliminary active layer 530 may begin before the hydrogen content of the thin film is sufficiently lowered. Accordingly, since the hydrogen content of the thin film is not sufficiently lowered, the defects such as the film bursting may occur.

When the intensity ratio I5 of the fifth peak P5 relative to the third peak P3 is less than about 50%, the annealing uniformity may be small. Accordingly, the quality of the display device may be decreased.

When the intensity ratio I5 of the fifth peak P5 relative to the third peak P3 exceeds about 65%, the process margin may be small.

In an embodiment, pulse duration between the first peak P1 and the second peak P2 may be about 14 nanoseconds (ns) to about 22 ns, pulse duration D1 between the first peak P1 and the third peak P3 may be about 43 ns to about 51 ns, pulse duration between the first peak P1 and the fourth peak P4 may be about 64 ns to about 72 ns, pulse duration between the first peak P1 and the fifth peak P5 may be about 79 ns to about 87 ns, and pulse duration between pulse begin s and pulse end e may be about 160 ns. Among the pulse durations, in the dehydrogenation process and the annealing process, the pulse duration D1 between the first peak P1 and the third peak P3 may be important.

When the pulse duration D1 between the first peak P1 and the third peak P3 is less than about 43 ns, the intensity of the second peak P2 may be increased, and then the film bursting may occur.

When the pulse duration D1 between the first peak P1 and the third peak P3 exceeds about 51 ns, the pulse duration D1 between the first P1 and the third peak P3 may be insufficient to induce the dehydrogenation from the thin film, and then the film bursting may occur.

As shown in FIG. 3, a second pulse shape PS2 may include a plurality of peaks. In an embodiment, the second pulse shape PS2 may include a first peak P21, a second peak P22, a third peak P23, a fourth peak P24, a fifth peak P25, a sixth peak P26, and a seventh peak P27. The first peak P21 may have the smallest peak occurrence time among the plurality of peaks. The second peak P22, the third peak P23, the fourth peak P24, the fifth peak P25 the sixth peak P26, and the seventh peak P27 may sequentially occur after the first peak P21 occurs. In other words, the second peak P22 may occur later than the first peak P21, the third peak P23 may occur later than the second peak P22, and the fourth peak P24 may occur later than the third peak P23, the fifth peak P25 may occur later than the fourth peak P24, the sixth peak P26 may occur later than the fifth peak P25, and the seventh peak P27 may occur later than the sixth peak P26.

The individual intensity ratio of each of the plurality of peaks may be calculated by dividing the individual intensity of each of the plurality of peaks by the reference intensity. The reference intensity may be a value for determining the second pulse shape PS2 including the plurality of peaks.

In an embodiment, the reference intensity may be equal to a height value of the fifth peak P25. Each of an intensity ratio I21 of the first peak P21, an intensity ratio I22 of the second peak P22, an intensity ratio I23 of the third peak P23, an intensity ratio I24 of the fourth peak P24, an intensity ratio I26 of the sixth peak P26, and an intensity ratio I27 of the seventh peak P27 may be set using the height value of the fifth peak P25 as the reference intensity. Accordingly, the intensity ratio I25 of the fifth peak P5 maybe 100% as the maximum value.

In an embodiment, the second pulse shape PS2 may be set so that the intensity ratio I21 of the first peak P21 is less than about 100% relative to the reference intensity. The reference intensity may be equal to the height value of the fifth peak P25. In other words, a value obtained by dividing an intensity of the first peak P21 by an intensity of the fifth peak P25 may be less than about 100%.

The individual intensity ratio of each of the plurality of peaks relative to the fifth peak P25 may be as follows. In an embodiment, the intensity ratio I21 of the first peak P21 may be about 18% to about 26%, the intensity ratio I22 of the second peak P22 may be about 1% to about 5%, the intensity ratio I23 of the third peak P23 may be about 30% to about 40%, the intensity ratio I24 of the fourth peak P24 may be about 10% to about 20%, the intensity ratio I26 of the sixth peak P26 may be about 40% to about 50%, and the intensity ratio I27 of the seventh peak P27 may be about 60% to about 75%. Among each of the intensity ratio of the peaks, in the dehydrogenation process and the annealing process, the intensity ratio I21 of the first peak P21 relative to the fifth peak P25 and the intensity ratio I27 of the seventh peak P27 relative to the fifth peak P25 may be important.

When the intensity ratio I21 of the first peak P21 relative to the fifth peak P25 is less than about 18%, the intensity ratio I21 of the first peak P21 relative to the fifth peak P25 may be insufficient to induce the dehydrogenation from the thin film. Even when the intensity ratio I23 of the third peak P23 relative to the fifth peak P25 is less than about 30%, the intensity ratio I23 may be also insufficient to induce the dehydrogenation from the thin film.

When the intensity ratio I21 of the first peak P21 relative to the fifth peak P25 exceeds about 26%, an amount of hydrogen release may be small, and then the defects such as the film bursting may occur. Even when the intensity ratio I23 of the third peak P23 exceeds about 40%, the amount of hydrogen release may be small, and then the defects such as the film bursting may occur.

When the intensity ratio I27 of the seventh peak P27 relative to the fifth peak P25 is less than about 50%, the annealing uniformity may be small. Accordingly, the quality of the display device may be decreased. When the intensity ratio I27 of the seventh peak P27 exceeds about 75%, the process margin may be small.

In an embodiment, pulse duration between the first peak P21 and the second peak P22 may be about 24 ns to about 32 ns, pulse duration D21 between the first peak P21 and the third peak P23 may be about 38 ns to about 46 ns, pulse duration between the first peak P21 and the fourth peak P24 may be about 49 ns to about 58 ns, pulse duration D22 between the first peak P21 and the fifth peak P25 may be about 83 ns to about 91 ns, pulse duration between the first peak P21 and the sixth peak P26 may be about 104 ns to about 112 ns, pulse duration D23 between the first peak P21 and the seventh peak P27 may be about 129 ns to about 137 ns, and pulse duration between the pulse beginning “s” and the pulse ending “e” may be about 186 ns to about 194 ns. Among the pulse durations, in the dehydrogenation process and the annealing process, the pulse duration D21 between the first peak P21 and the third peak P23, the pulse duration D22 between the first peak P21 and the fifth peak P25, and the pulse duration D23 between the first peak P21 and the seventh peak P27 may be important.

When the pulse duration D21 between the first peak P21 and the third peak P23 is less than about 38 ns or the pulse duration D22 between the first peak P21 and the fifth peak P25 is less than about 83 ns, the intensity of the peak occurred after the first peak P21 (e.g., the third peak P23) may be increased, and then the defects such as the film bursting may occur.

When the pulse duration D21 between the first peak P21 and the third peak P23 exceeds about 46 ns or the pulse duration D22 between the first peak P21 and the fifth peak P25 exceeds about 91 ns, the amount of hydrogen release may be small, and then the defects such as the film bursting may occur.

On the other hand, the pulse duration D23 between the first peak P21 and the seventh peak P27 is less than about 129 ns or exceeds about 137 ns, the process margin may be small.

When processing using the laser beam LS set the second pulse shape PS2, the amount of hydrogen release may be larger than when processing using the laser beam LS set the first pulse shape PS1.

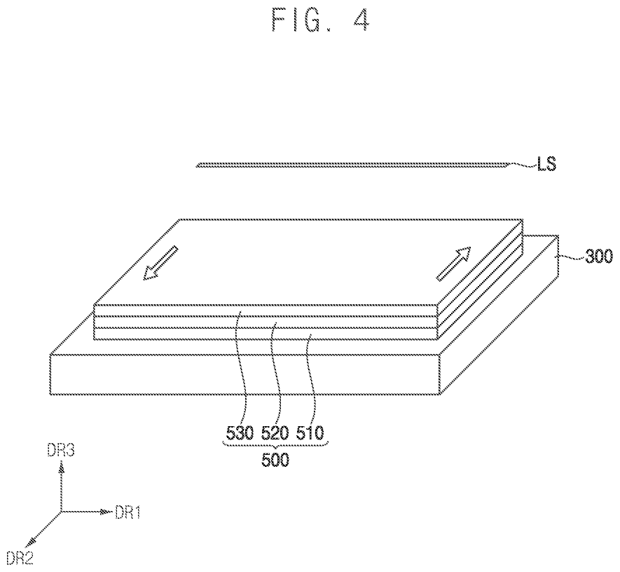

FIG. 4 is a perspective view illustrating the laser annealing method according to an embodiment of the present disclosure. For example, FIG. 4 is a perspective view to explain the method of the laser beam LS having the pulse shape (e.g., the first pulse shape PS1 of FIG. 1 or the second pulse shape PS2 of FIG. 3) irradiated to the stage 300.

Referring to FIG. 4, the laser beam LS having the pulse shape as specified above may be irradiated to the stage 300. In an embodiment, the laser beam LS may be set to have a first energy density and then the stage 300 may be first scanned using the laser beam LS having the first energy density.

In an embodiment, the laser beam LS may be irradiated to the stage 300 in a shape of a line beam extending a first direction DR1. However, the present disclosure may not be limited thereto, and the laser beam LS may be irradiated in various shapes such as a rectangular planar shape, and a dot.

Next, the laser beam LS may be set to have a second energy density and then the stage 300 may be scanned a second time using the laser beam LS having the second energy density.

In an embodiment, a second scan may proceed along an opposite direction to a first scan. That is, the first scan may proceed along a second direction DR2 perpendicular to the first direction DR1, and the second scan may proceed in the opposite direction to the second direction DR2. For example, the dehydrogenation process may proceed during the first scan, and then the annealing process may proceed during the second scan.

The energy density (e.g., the first energy density and the second energy density) may be defined as a total amount of energy in the object 500 per unit volume. In an embodiment, the laser beam LS may have the first energy density during the first scan and may have the second energy density during the second scan. The first energy density may be a dehydrogenation energy density, and the second energy density may be an annealing energy density. The annealing energy density may be greater than the dehydrogenation energy density.

In an embodiment, the first energy density may be about 60% to about 80% of the second energy density. In other words, the first energy density used in the dehydrogenation process may be about 60 to about 80% of a central energy of the second energy density used in the annealing process. By first performing the dehydrogenation process and then performing the annealing process, the occurrence of the defects due to the heat accumulation may be prevented.

In an embodiment, the energy densities (e.g., the first energy density and the second energy density) may be set differently according to a thickness of the preliminary active layer 530. Specifically, as the thickness of the preliminary active layer 530 increases, the energy densities of the laser beam LS may be set higher.

For example, when the thickness of the preliminary active layer 530 is about 470 angstroms (Å), the dehydrogenation energy density may be set to about 420 milli-joules per square centimeter (mJ/cm²), and the annealing energy density may be set about 593 mJ/cm². For another example, when the thickness of the preliminary active layer 530 is about 500 Å, the dehydrogenation energy density may be set about 440 mJ/cm², and the annealing energy density may be set to about 618 mJ/cm². However, the present disclosure may not be limited thereto, and an energy density value may vary depending on a size of the laser beam LS and the like.

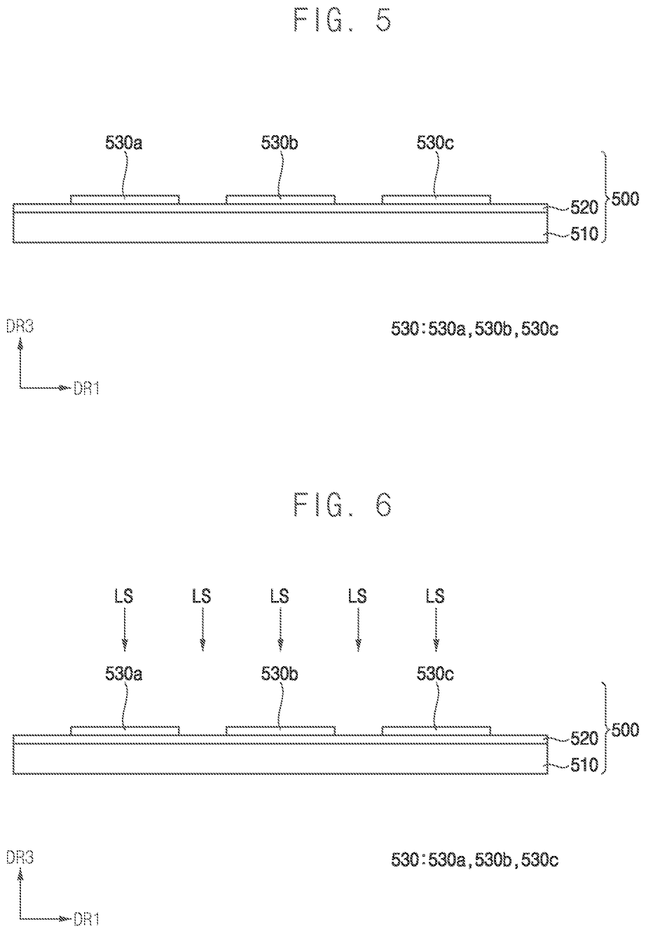

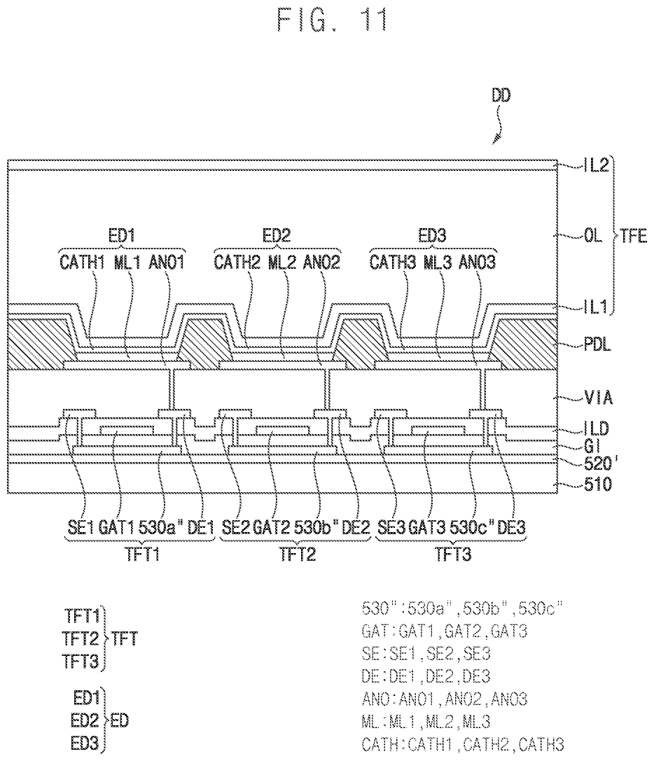

FIGS. 5, 6, 7, 8, 9, 10, and 11 are cross-sectional views illustrating a method of manufacturing a display device according to another embodiment of the present disclosure using the laser annealing method according to an embodiment of the present disclosure. Hereinafter, overlapping descriptions with the laser annealing method described above with reference to FIGS. 1, 2, 3, and 4 will be omitted or simplified.

First, the laser annealing method will be described.

Referring to FIG. 5, the insulating layer 520 may be formed on the substrate 510. The preliminary active layer 530 may be formed on the insulating layer 520. For example, the preliminary active layer 530 may include the amorphous silicon. In this case, the substrate 510, the insulating layer 520, and the preliminary active layer 530 may be defined as the object 500. The preliminary active layer 530 may include a first preliminary active layer 530a, a second preliminary active layer 530b, and a third preliminary active layer 530c.

Referring to FIG. 6, the object 500 may be first irradiated (i.e., a first irradiation) by the laser beam LS. Specifically, the laser beam LS may be first directed to irradiating the insulating layer 520 and the preliminary active layer 530 of the object 500. In other words, the laser beam LS may be first directed to irradiating the insulating layer 520, the first preliminary active layer 530a, the second preliminary active layer 530b, and the third preliminary active layer 530c. Accordingly, a first irradiated treated object 500′ may be formed.

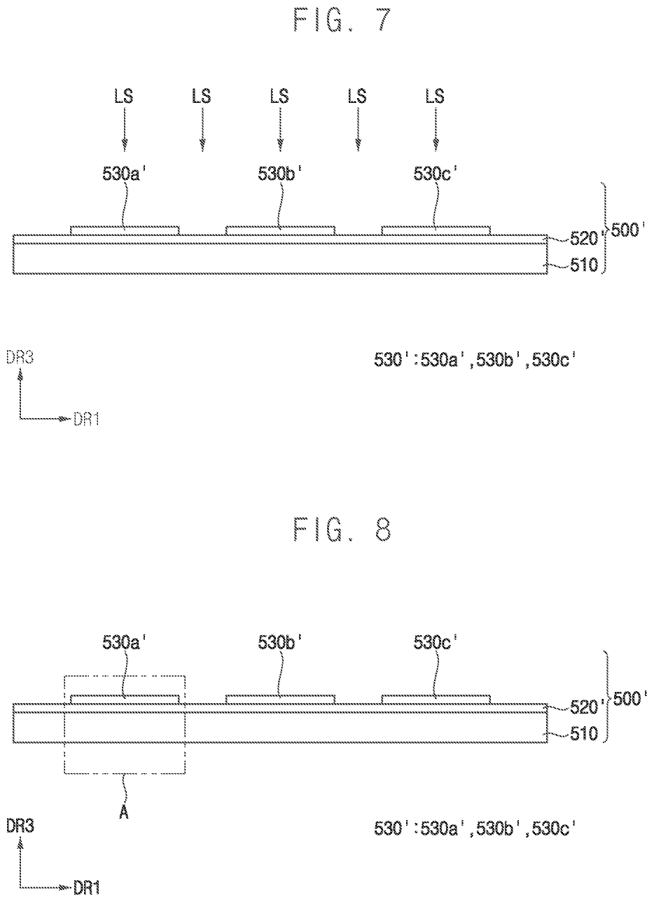

Referring to FIG. 7, the laser beam LS may be directed to a second irradiation of the first irradiated treated object 500′. Specifically, the laser beam LS may be directed to a second irradiation of a preliminary active layer 530′ which has already been subjected to a first irradiation. In other words, the laser beam LS may be directed to a second irradiation of each of the first preliminary active layer 530a′, the second preliminary active layer 530b′, and the third preliminary active layer 530c′ each of which have already been subjected to a first irradiation. Accordingly, the second irradiated object 500″ may be formed.

The laser beam LS may have the pulse shape (e.g., the first pulse shape PS1 of FIG. 2 or the second pulse shape PS2 of FIG. 3). The pulse shape may be set such that the intensity ratio of the first peak (e.g., the intensity ratio I1 of the first peak P1 of FIG. 2 or the intensity ratio I21 of the first peak P21) is less than about 100% relative to the reference intensity.

The reference intensity may be the value for determining the pulse shape. The plurality of peaks may be included in the pulse shape.

In an embodiment, as shown in FIG. 2, the height value of the third peak P3 may be set as the reference intensity.

In another embodiment, as shown in FIG. 3, the height value of the fifth peak P25 may be set as the reference intensity.

As described above, by setting the pulse shape having the intensity ratio of the first peak relative to the reference intensity is less than about 100%, the defects due to the heat accumulation may be prevented and the annealing uniformity may be improved.

The laser beam LS may have a first energy density during the first scan (corresponding to the first irradiation) and may have a second energy density during the second scan (corresponding to the second irradiation). By first performing the dehydrogenation process using the laser beam LS and then performing the annealing process, defects can be minimized Specifically, the preliminary active layer 530′ after being first irradiated to facilitate dehydrogenation may then be annealed by a second irradiation with the laser LS.

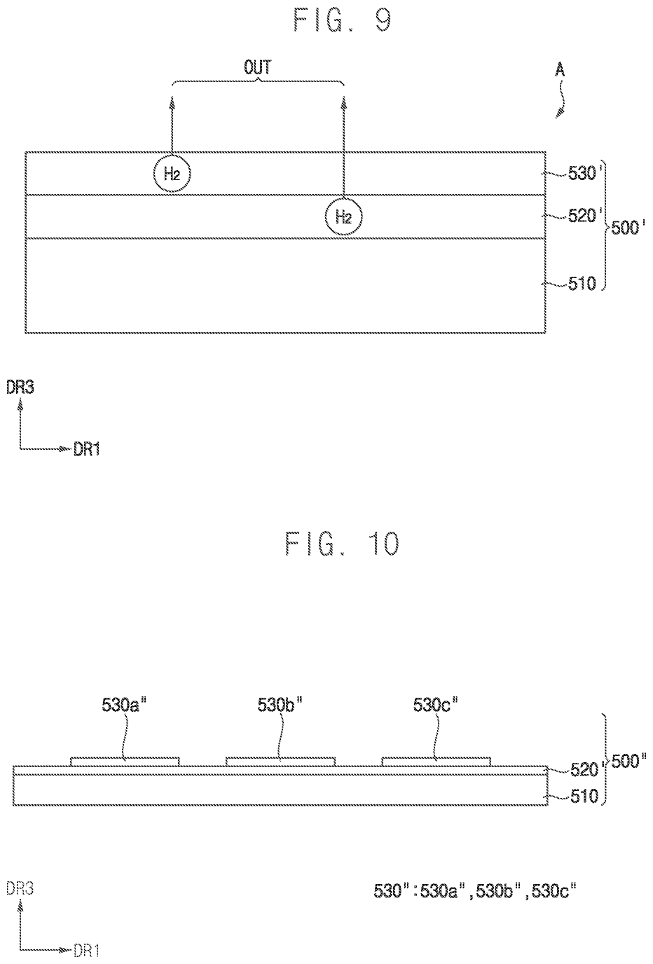

Referring to FIGS. 8 and 9, hydrogen (H₂) may be released from the insulating layer 520′ and the preliminary active layer 530′ through the first irradiation. After lowering the hydrogen content of the insulating layer 520′ and the preliminary active layer 530′ through the first irradiation, the second irradiation (e.g., the annealing process) may be performed. Accordingly, the defects such as film bursting may be prevented.

Referring to FIGS. 8, 9 and 10, the first irradiation and second irradiation treated object 500″ may include an active layer 530″ including polycrystalline silicon. That is, the preliminary active layer 530′ including the amorphous silicon may be annealed by the laser beam LS, and then the active layer 530″ including polycrystalline silicon may be formed. Hereinafter, the method of manufacturing the display device DD proceeding after the annealing process using the laser beam LS.

Referring to FIG. 11, a gate insulating layer GI may be formed on the insulating layer 520′. The gate insulating layer GI may be formed to cover the active layer 530″. The gate insulating layer GI may be formed using an inorganic insulating material.

A gate electrode GAT may be formed on the gate insulating layer GI. The gate electrode GAT may be formed to partially overlap the active layer 530″. The gate electrode GAT may be formed using metal, a metal oxide, a metal nitride, or the like.

An interlayer insulating layer ILD may be formed on the gate insulating layer GI. The interlayer insulating layer ILD may be formed to cover the gate electrode GAT. The interlayer insulating layer ILD may be formed using an inorganic insulating material.

Each of a source electrode SE and a drain electrode DE may be formed on the interlayer insulating layer ILD. Each of the source electrode SE and the drain electrode DE may be connected to the active layer 530″ through a contact hole. Each of the source electrode SE and the drain electrode DE may be formed using metal, metal oxide, metal nitride, or the like.

Accordingly, a first transistor TFT1, a second transistor TFT2, and a third transistor TFT3 may be formed on the substrate 510. The first transistor TFT1 may include a first active layer 530a″, a first gate electrode GAT1, a first source electrode SE1, and a first drain electrode DEE The second transistor TFT2 may include a second active layer 530b″, a second gate electrode GAT2, a second source electrode SE2, and a second drain electrode DE2. The third transistor TFT3 may include a third active layer 530c″, a third gate electrode GATS, a third source electrode SE3, and a third drain electrode DE3.

A via insulating layer VIA may be formed on the interlayer insulating layer ILD. The via insulating layer VIA may be formed to cover the source electrode SE and the drain electrode DE. The via insulating layer VIA may be formed to have a substantially flat upper surface. The via insulating layer VIA may be formed using an organic insulating material.

An anode electrode ANO may be formed on the via insulating layer VIA. The anode electrode ANO may be connected to the drain electrode DE. The anode electrode ANO may be formed using metal, metal oxide, metal nitride, or the like.

A pixel defining layer PDL may be formed on the via insulating layer VIA. An opening exposing each of a first electrode ANO1, a second electrode ANO2, and a third electrode ANO3 may be formed in the pixel defining layer PDL. The pixel defining layer PDL may be formed using an organic insulating material.

An intermediate layer ML may be formed on the anode electrode ANO. The intermediate layer ML may be formed using an organic material. In the intermediate layer ML, an electron injection layer, an electron transport layer, a light emitting layer, a hole transport layer, and a hole injection layer may be sequentially formed.

A cathode electrode CATH may be formed on the intermediate layer ML. The cathode electrode CATH may include a first cathode electrode CATH1, a second cathode electrode CATH2, and a third cathode electrode CATH3. The first cathode electrode CATH1 may be formed on the first transistor TFT1, the second cathode electrode CATH2 may be formed on the second transistor TFT2, and the third cathode electrode CATH3 may be formed on the third transistor TFT3. Alternatively, the first cathode electrode CATH1, the second cathode electrode CATH2, and the third cathode electrode CATH3 may be formed in a connected form.

Accordingly, a first light emitting device ED1 including the first anode electrode ANO1, a first intermediate layer ML1, and the cathode electrode CATH may be formed on the substrate 510. A second light emitting device ED2 including the second anode electrode ANO2, a second intermediate layer ML2, and the cathode electrode CATH may be formed on the substrate 510. A third light emitting device ED3 including the third anode electrode ANO3, a third intermediate layer ML3, and the cathode electrode CATH may be formed on the substrate 510.

Each of the first light emitting device ED1, the second light emitting device ED2, and the third light emitting device ED3 may emit same color light. For example, each of the first light emitting device ED1, the second light emitting device ED2, and the third light emitting device ED3 may emit blue light altogether. Alternatively, each of the first light emitting device ED1, the second light emitting device ED2, and the third light emitting device ED3 may emit different color light each other. For example, the first light emitting device ED1 may emit red light, the second light emitting device ED2 may emit green light, and the third light emitting device ED3 may emit the blue light. However, the present disclosure may not be limited thereto.

A thin film encapsulation layer TBE may be formed on the cathode electrode CATH. The thin film encapsulation layer TFE may include a first inorganic layer ILL an organic layer OL, and a second inorganic layer IL2. The first inorganic layer ILL an organic layer OL, and a second inorganic layer IL2 may be sequentially formed. The organic layer OL may be formed to have a relatively thick thickness and a flat top surface compared to the first inorganic layer IL1 and the second inorganic layer IL2. The thin film encapsulation layer TFE may further include additional inorganic layer and/or additional organic layer.

Accordingly, the display device DD as showed in FIG. 11 may be manufactured.

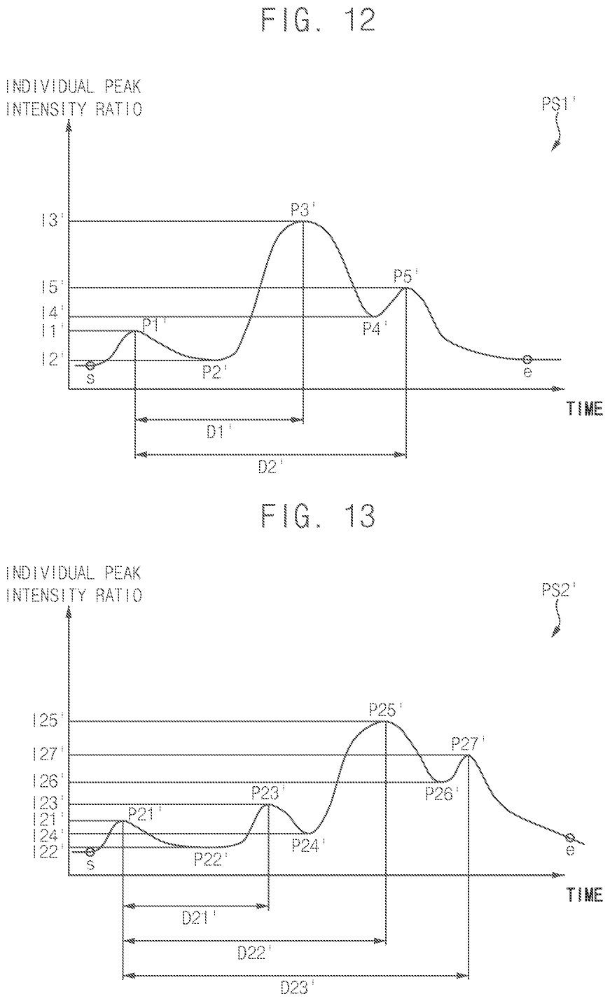

FIGS. 12 and 13 are graphs illustrating other pulse shapes set by the laser annealing apparatus of FIG. 1.

For example, pulse duration between the pulse beginning “s” and the pulse ending “e” of a first modulation pulse shape PS1′ of FIG. 12 may be larger than the pulse duration between the pulse beginning “s” and the pulse ending “e” of the first pulse shape PS1 of FIG. 2. Pulse duration between the pulse beginning “s” and the pulse ending “e” of a second modulation pulse shape PS2′ of FIG. 12 may be larger than the pulse duration between the pulse beginning “s” and the pulse ending “e” of the second pulse shape PS2 of FIG. 3. Accordingly, when processing using the laser beam LS set the first pulse shape PS1, the amount of hydrogen release may be larger than when processing using the laser beam LS set the first modulation pulse shape PS1′. When processing using the laser beam LS set the second pulse shape PS2, the amount of hydrogen release may be larger than when processing using the laser beam LS set the second modulation pulse shape PS2′. Hereinafter, overlapping descriptions with the pulse shapes PS1, PS2 described above with reference to FIGS. 2 and 3 will be omitted or simplified.

Referring to FIG. 12, the first modulation pulse shape PS1′ may include a first peak P1′, a second peak P2′, a third peak P3′, a fourth peak P4′, and a fifth peak P5′. The first peak P1′ may have the smallest peak occurrence time among the plurality of peaks. The second peak P2′, the third peak P3′, the fourth peak P4′, and the fifth peak P5′ may sequentially occur after the first peak P1′ occurs.

The individual intensity ratio of each of the plurality of peaks may be calculated by dividing the individual intensity of each of the plurality of peaks by the reference intensity. The reference intensity may be a value for determining the first modulation pulse shape PS1′ including the plurality of peaks.

In an embodiment, the reference intensity may be equal to a height value of the third peak P3′. Each of an intensity ratio IF of the first peak P1′, an intensity ratio I2′ of the second peak P2′, an intensity ratio I4 of the fourth peak P4′, and an intensity ratio I5′ of the fifth peak P5′ may be set using the height value of the third peak P3′ as the reference intensity. Accordingly, the intensity ratio I3′ of the third peak P3′ maybe 100% of the maximum value and hence is selected as the reference intensity.

The individual intensity ratio of each of the plurality of peaks relative to the third peak P3′ may be as follows. In an embodiment, the intensity ratio IF of the first peak P1′ may be about 24% to about 32%, the intensity ratio I2′ of the second peak P2′ may be about 1% to about 4%, the intensity ratio I4′ of the fourth peak P4′ may be about 28% to about 36%, and the intensity ratio I5′ of the fifth peak P5′ may be about 54% to about 62%. When the intensity ratio I1′ of the first peak P1′ and the intensity ratio I5′ of the fifth peak P5′ are out of a range of the individual peak intensity ratios, the process margin may be decreased.

In an embodiment, pulse duration between the first peak P1′ and the second peak P2′ is about 31 ns to about 39 ns, pulse duration D1′ between the first peak P1′ and the third peak P3′ is about 62 ns to about 74 ns, pulse duration between the first peak P1′ and the fourth peak P4′ is about 91 ns to about 103 ns, and pulse duration D2′ between the first peak P1′ and the fifth peak P5′ is about 104 ns, and 116 ns, and pulse duration between pulse begin s and pulse end e is about 200 ns. When the pulse duration D1′ between the first peak P1′ and the third peak P3′ and the pulse duration D2′ between the first peak P1′ and the fifth peak P5′ are out of a range of the pulse durations, the process margin may be decreased.

Referring to FIG. 13, the second modulation pulse shape PS2′ may include a first peak P21′, a second peak P22′, a third peak P23′, a fourth peak P24′, a fifth peak P25′, a sixth peak P26′, and a seventh peak P27′. The first peak P21′ may have the smallest peak occurrence time among the plurality of peaks. The second peak P22′, the third peak P23′, the fourth peak P24′, the fifth peak P25′, the sixth peak P26′, and the seventh peak P27′ may sequentially occur after the first peak P21′ occurs.

The individual intensity ratio of each of the plurality of peaks may be calculated by dividing the individual intensity of each of the plurality of peaks by the reference intensity. The reference intensity may be a value for determining the second modulation pulse shape PS2′ including the plurality of peaks.

In an embodiment, the reference intensity may be equal to a height value of the fifth peak P25′. Each of an intensity ratio I21′ of the first peak P21′, an intensity ratio I22′ of the second peak P22′, an intensity ratio I23 of the third peak P23′, an intensity ratio I24 of the fourth peak P24′, an intensity ratio I26′ of the sixth peak P26′, and an intensity ratio I27′ of the seventh peak P27′ may be set using the height value of fifth peak P25′ as the reference intensity. Accordingly, the intensity ratio I25′ of the fifth peak P25′ maybe 100% of the maximum value and hence is selected as the reference intensity.

The individual intensity ratio of each of the plurality of peaks relative to the fifth peak P25′ may be as follows. In an embodiment, the intensity ratio I21′ of the first peak P21′ may be about 18% to about 26%, the intensity ratio I22′ of the second peak P22′ may be about 1% to about 5%, the intensity ratio I23′ of the third peak P23′ may be about 30% to about 40%, the intensity ratio I24′ of the fourth peak P24′ may be about 10% to about 20%, the intensity ratio I25′ of the fifth peak P25′ may be about 100%, the intensity ratio I26′ of the sixth peak P26′ may be about 40% to about 50%, and the intensity ratio I27′ of the seventh peak P27′ may be about 60% to about 75%. When the intensity ratio I21′ of the first peak P21′ and the intensity ratio I27′ of the seventh peak P27′ relative to the fifth peak P25′ are out of a range of the individual peak intensity ratios, the process margin may be decreased.

In an embodiment, pulse duration between the first peak P21′ and the second peak P22′ is about 24 ns to about 32 ns, pulse duration D21′ between the first peak P21′ and the third peak P23′ is about 38 ns to about 46 ns, pulse duration between the first peak P21′ and the fourth peak P24′ is about 49 ns to about 58 ns, and pulse duration D22′ between the first peak P21′ and the fifth peak P25′ is about 83 ns, and 91 ns, pulse duration between the first peak P21′ and the sixth peak P26′ is about 104 ns, and 112 ns, pulse duration D23′ between the first peak P21′ and the seventh peak P27′ is about 129 ns, and 137 ns, and pulse duration between pulse begin s and pulse end e is about 186 ns to about 194 ns. When the pulse duration D21′ between the first peak P21′ and the third peak P23′, the pulse duration D22′ between the first peak P21′ and the fifth peak P25′, and the pulse duration D23′ between the first peak P21′ and the seventh peak P27′ are out of a range of the pulse durations, the process margin may be decreased.

As described above with reference to FIGS. 1, 2, 3, 4, 5, 6, 7, 8, 9, 10, 11, 12, and 13, in the laser annealing method according to the embodiments of the present disclosure the pulse shape P51, PS21, PS1′ or PS21′ may be set having the intensity ratio IL IF I21, or I21′ of the first peak P1, P21, P1′ or P21′ relative to the reference intensity and is less than about 100%, the defects due to the heat accumulation may be prevented by inducing the dehydrogenation and the annealing uniformity may be improved.

In addition, in the manufacturing method of the display device, the laser beam LS having the dehydrogenation energy density of about 60% to about 80% of the annealing energy density may be first irradiated on the object 500. And then, the laser beam LS having the annealing energy density may be second irradiated to the first irradiated treated object 500′. Accordingly, the defects such as the film bursting may be prevented, and durability of the display device may be improved.

The laser annealing method according to embodiments of the present disclosure may be applied to the method of manufacturing the display device such as a notebook, a mobile phone, a smartphone, a smart pad, a PMP, a PDA, an MP3 player.

The foregoing is illustrative of embodiments and is not to be construed as limiting thereof. Although a few embodiments have been described, those skilled in the art will readily appreciate that many modifications are possible in the embodiments without materially departing from the novel teachings and advantages of the disclosure. Accordingly, all such modifications are intended to be included within the scope of the disclosure.

Therefore, it is to be understood that the foregoing is illustrative of various embodiments and is not to be construed as limited to the specific embodiments disclosed, and that modifications to the disclosed embodiments, as well as other embodiments, are intended to be included within the scope of the disclosure.

What is claimed is:

1. A laser annealing method comprising:
selecting a reference intensity from a plurality of intensities of a plurality of peaks; where the reference intensity is used to determine a pulse shape of laser irradiation during laser annealing;
setting the pulse shape by setting an intensity ratio of a first peak having a smallest peak occurrence time among the plurality of peaks to less than about 100 percent relative to the reference intensity; and
irradiating a laser beam having the pulse shape to a stage.

2. The laser annealing method of claim 1, wherein the pulse shape further includes a second peak, a third peak, a fourth peak, and a fifth peak,
each of the second peak, the third peak, the fourth peak, and the fifth peak occur sequentially after occurrence of the first peak, and
the intensity ratio of each of the first peak, the second peak, the fourth peak, and the fifth peak is set using a height value of the third peak as the reference intensity.

3. The laser annealing method of claim 2, wherein the intensity ratio of the first peak relative to the third peak is about 60 percent to about 70 percent.

4. The laser annealing method of claim 3, wherein the intensity ratio of the fifth peak relative to the third peak is about 50 percent to about 65 percent.

5. The laser annealing method of claim 4, wherein pulse duration between the first peak and the third peak is about 43 nanoseconds to about 51 nanoseconds.

6. The laser annealing method of claim 2, wherein the intensity ratio of the first peak relative to the third peak is about 24 percent to about 32 percent.

7. The laser annealing method of claim 6, wherein the intensity ratio of the fifth peak relative to the third peak is about 54 percent to about 62 percent.

8. The laser annealing method of claim 7, wherein the pulse duration between the first peak and the third peak is about 62 nanoseconds to about 74 nanoseconds, and
the pulse duration between the first peak and the fifth peak is about 104 nanoseconds to about 116 nanoseconds.

9. The laser annealing method of claim 1, wherein the pulse shape further includes a second peak, a third peak, a fourth peak, a fifth peak, a sixth peak, and a seventh peak,
each of the second peak, the third peak, the fourth peak, and the fifth peak, a sixth peak, and the seventh peak occur sequentially after occurrence of the first peak, and
the intensity ratio of each of the first peak, the second peak, the third peak, the fourth peak, the sixth peak, and the seventh peak is set using a height value of the fifth peak as the reference intensity.

10. The laser annealing method of claim 9, wherein the intensity ratio of the first peak relative to the fifth peak is about 18 percent to about 26 percent.

11. The laser annealing method of claim 10, wherein the intensity ratio of the third peak relative to the fifth peak is about 30 percent to about 40 percent, and
the intensity ratio of the seventh peak relative to the fifth peak is about 60 percent to about 75 percent.

12. The laser annealing method of claim 11, wherein pulse duration between the first peak and the third peak is about 38 nanoseconds to about 46 nanoseconds,
the pulse duration between the first peak and the fifth peak is about 83 nanoseconds to about 91 nanoseconds, and
the pulse duration between the first peak and the seventh peak is about 129 nanoseconds to about 137 nanoseconds.

13. The laser annealing method of claim 10, wherein the intensity ratio of the third peak relative to the fifth peak is about 31 percent to about 39 percent, and
the intensity ratio of the seventh peak relative to the fifth peak is about 61 percent to about 70 percent.

14. The laser annealing method of claim 13, wherein the pulse duration between the first peak and the third peak is about 52 nanoseconds to about 64 nanoseconds,
the pulse duration between the first peak and the fifth peak is about 98 nanoseconds to about 110 nanoseconds, and
the pulse duration between the first peak and the seventh peak is about 133 nanoseconds to about 143 nanoseconds.

15. The laser annealing method of claim 1, wherein the irradiation of the laser beam to the stage includes,
setting the laser beam having a first energy density;
first scanning the stage using the laser beam irradiation in a shape of a line beam extending a first direction, along a second direction perpendicular to the first direction;
setting the laser beam having a second energy density larger than the first energy density; and
second scanning the stage using the laser beam having the second energy density, along an opposite direction to the second direction.

16. A method of manufacturing a display device, the method comprising:
forming a preliminary active layer including amorphous silicon on a substrate;
setting a reference intensity for determining a pulse shape including a plurality of peaks;
setting the pulse shape having an intensity ratio of a first peak having a smallest peak occurrence time among the plurality of peaks less to than about 100 percent relative to the reference intensity; and
annealing the preliminary active layer by irradiating a laser beam having the pulse shape.

17. The method of claim 16, wherein,
the pulse shape further includes a second peak, a third peak, a fourth peak, and a fifth peak,
each of the second peak, the third peak, the fourth peak, and the fifth peak occur sequentially after occurrence of the first peak,
the intensity ratio of each of the first peak, the second peak, the fourth peak, and the fifth peak is set using a height value of the third peak as the reference intensity,
the intensity ratio of the first peak relative to the third peak is about 60 percent to about 70 percent,
the intensity ratio of the fifth peak relative to the third peak is about 50 percent to about 65 percent, and
pulse duration between the first peak and the third peak is about 43 nanoseconds to about 51 nanoseconds.

18. The method of claim 16, wherein,
the pulse shape further includes a second peak, a third peak, a fourth peak, and a fifth peak,
each of the second peak, the third peak, the fourth peak, and the fifth peak occur sequentially after occurrence of the first peak,
the intensity ratio of each of the first peak, the second peak, the fourth peak, and the fifth peak is set using a height value of the third peak as the reference intensity,
the intensity ratio of the first peak relative to the third peak is about 24 percent to about 32 percent,
the intensity ratio of the fifth peak relative to the third peak is about 54 percent to about 62 percent,
pulse duration between the first peak and the third peak is about 62 nanoseconds to about 74 nanoseconds, and
the pulse duration between the first peak and the fifth peak is about 104 nanoseconds to about 116 nanoseconds.

19. The method of claim 16, wherein,
the pulse shape includes the first peak, a second peak, a third peak, a fourth peak, a fifth peak, a sixth peak, and a seventh peak,
each of the second peak, the third peak, the fourth peak, and the fifth peak, a sixth peak, and the seventh peak occur sequentially after occurrence of the first peak,
the intensity ratio of each of the first peak, the second peak, the fourth peak, and the fifth peak is set using a height value of the fifth peak as the reference intensity,
the intensity ratio of the first peak relative to the fifth peak is about 18 percent to about 26 percent,
the intensity ratio of the third peak relative to the fifth peak is about 30 percent to about 40 percent,
the intensity ratio of the seventh peak relative to the fifth peak is about 60 percent to about 75 percent,
pulse duration between the first peak and the third peak is about 38 nanoseconds to about 46 nanoseconds,
the pulse duration between the first peak and the fifth peak is about 83 nanoseconds to about 91 nanoseconds, and
the pulse duration between the first peak and the seventh peak is about 129 nanoseconds to about 137 nanoseconds.

20. The method of claim 16, wherein,
the pulse shape includes the first peak, a second peak, a third peak, a fourth peak, a fifth peak, a sixth peak, and a seventh peak,
each of the second peak, the third peak, the fourth peak, and the fifth peak, a sixth peak, and the seventh peak occur sequentially after occurrence of the first peak,
the intensity ratio of each of the first peak, the second peak, the fourth peak, and the fifth peak is set using a height value of the fifth peak as the reference intensity,
the intensity ratio of the first peak relative to the fifth peak is about 18 percent to about 26 percent,
the intensity ratio of the third peak relative to the fifth peak is about 31 percent to about 39 percent,
the intensity ratio of the seventh peak relative to the fifth peak is about 61 percent to about 70 percent,
pulse duration between the first peak and the third peak is about 52 nanoseconds to about 64 nanoseconds,
the pulse duration between the first peak and the fifth peak is about 98 nanoseconds to about 110 nanoseconds, and
the pulse duration between the first peak and the seventh peak is about 133 nanoseconds to about 143 nanoseconds.
